(19) United States
(12) Patent Application Publication
(10) Pub. No.: US 2024/0094986 A1
(43) Pub. Date: Mar. 21, 2024

(54) METHOD AND APPARATUS FOR MATRIX COMPUTATION USING DATA CONVERSION IN A COMPUTE ACCELERATOR

(71) Applicant: d-MATRIX CORPORATION, Cupertino, CA (US)

(72) Inventors: Ilya LYUBOMIRSKY, Pleasanton, CA (US); Irene QUEK, Los Altos, CA (US); Arun TIRUVUR, San Jose, CA (US); Satyam SRIVASTAVA, El Dorado Hills, CA (US); Sudeep BHOJA, Cupertino, CA (US)

(21) Appl. No.: 17/896,925

(22) Filed: Aug. 26, 2022

(51) Int. Cl. G06F 9/38; G06F 7/499; G06F 9/30

(52) U.S. Cl. CPC G06F 9/3887; G06F 7/49915; G06F 7/49942; G06F 9/30032; G06F 9/30036

(57) ABSTRACT

A method and device for data conversion in a matrix compute apparatus. The apparatus includes an input buffer (IB) that receives one or more matrix inputs characterized by a first format and a compute device coupled to the IB device that is configured to determine a combined matrix output. The compute device determines a first matrix output using a first input portion of the matrix input and determines a second matrix output using a second input portion. The compute device then determines a combined matrix output in a second format using the first and second matrix outputs. Within the compute device, an alignment device can determine a rounded matrix output from the combined matrix output, and a partial products reduction (PPR) device can determine a reduced matrix output in a third format using the rounded matrix output, which is stored in an output buffer (OB) coupled to the compute device.

### BACKGROUND OF THE INVENTION

The present invention relates generally to integrated circuit (IC) devices and artificial intelligence (AI). More specifically, the present invention relates to methods and device structures for accelerating computing workloads, such as those in transformer-based models (a.k.a. transformers).

The transformer has been the dominant neural network architecture in the natural language processing (NLP) field, and its use continues to expand into other machine learning applications. The original Transformer was introduced in the paper “Attention is all you need” (Vaswani et al., 2017), which sparked the development of many transformer model variations, such as the generative pre-trained transformer (GPT) and the bidirectional encoder representations from transformers (BERT) models. Such transformers have significantly outperformed other models in inference tasks by their use of a self-attention mechanism that avoids recursion and allows for easy parallelism. On the other hand, the transformer workloads are very computationally intensive and have high memory requirements, and have been plagued as being time-intensive and inefficient.

Most recently, NLP models have grown by a thousand times in both model size and compute requirements. For example, it can take about 4 months for 1024 graphics processing units (GPUs) to train a model like GPT-3 with 175 billion parameters. New NLP models having a trillion parameters are already being developed, and multi-trillion parameter models are on the horizon. Such rapid growth has made it increasingly difficult to serve NLP models at scale.

From the above, it can be seen that improved devices and methods to accelerate compute workloads for AI are highly desirable.

### BRIEF SUMMARY OF THE INVENTION

The present invention relates generally to integrated circuit (IC) devices and artificial intelligence (AI) systems. More particularly, the present invention relates to methods and device structures for accelerating computing workloads, such as those in transformer-based neural network models (a.k.a. transformers) and the like. These methods and structures can be used in machine/deep learning applications such as natural language processing (NLP), computer vision (CV), and the like. Merely by way of example, the invention has been applied to AI accelerator apparatuses and chiplet devices configured in a PCIe card.

According to an example, the present invention relates to data conversion in a matrix compute apparatus. In certain applications, it is desirable for the matrix compute apparatus to have the capability of handling other numerical formats in addition to its own native numerical format. Thus, the present invention provides for a method and device to enable a matrix compute apparatus configured to process matrix data in a target format by segmenting the data and parallel processing the segmented data portions in the native format of the matrix compute apparatus.

The matrix compute apparatus can include an input buffer (IB) device, a compute device coupled to the IB device, and an output buffer (OB) device coupled to the compute device. The IB device is configured to receive one or more matrix inputs characterized by a first format and having at least a first input portion and a second input portion. The compute device has a plurality of compute units, including at least a first compute unit and a second compute unit. For each matrix input, the compute device is configured to determine a first matrix output and a second matrix output from the first input portion and the second input portion, respectively. The compute device then determines a combined matrix output in a second format using the first and second matrix outputs.

In an example, each of the matrix inputs includes a matrix weight and a matrix activation. Each of the matrix weight and the matrix activation can include an exponent and a mantissa. The matrix weight mantissa can be separated into a first portion and a second portion, which are stored in the first compute unit and second compute unit, respectively. In this case, the compute device determines the first matrix output by performing a dot product process using the matrix activation and first portion of the matrix weight mantissa. Similarly, the compute device determines the second matrix output by performing a dot product process using the matrix activation and the second portion of the matrix weight mantissa. Determining the combined matrix output includes shifting the first matrix output and adding the first matrix output to the second matrix output.

In an example, the compute device includes an alignment device and a partial products reduction device coupled to the plurality of compute units. The alignment device can be configured to determine a rounded matrix output for each of the combined matrix outputs, and the PPR device can be configured to determine a reduced matrix output in a third format for each of the rounded matrix outputs. The compute device also includes a compute converter configured to determine a converted matrix output in a converted output format for each matrix input using the resulting matrix output from the compute device. Afterwards, the resulting converted matrix outputs are stored in the OB device.

Although the previous examples only discuss segmenting matrix data into two portions that are processed in parallel by two compute units, other embodiments of the present invention may segment the matrix data into a plurality of portions that are processed in parallel by a plurality of compute units. Embodiments of the matrix compute apparatus and its related methods can also be implemented in chiplet devices and AI accelerator systems. Those of ordinary skill in the art will recognize other variations, modifications, and alternatives.

Embodiments of this matrix compute apparatus and its related methods can provide many benefits. The present method and apparatus enables the computational handling of matrix inputs in different data formats that can be segmented into portions that are compatible with a native format. Also, this multi-format capability can be accomplished without requiring entirely separate hardware and compute pathways. In particular, a matrix multiply unit designed for efficient integer arithmetic, can be used for processing floating point data, such as IEEE FP16 or Bfloat16. Further, these benefits can be realized in IC chips and chiplet devices with minimal added cost of silicon area.

A further understanding of the nature and advantages of the invention may be realized by reference to the latter portions of the specification and attached drawings.

### BRIEF DESCRIPTION OF THE DRAWINGS

In order to more fully understand the present invention, reference is made to the accompanying drawings. Understanding that these drawings are not to be considered limitations in the scope of the invention, the presently described embodiments and the presently understood best mode of the invention are described with additional detail through use of the accompanying drawings in which:

FIG. 1A-1B are simplified block diagrams illustrating AI accelerator apparatuses according to examples of the present invention.

FIGS. 2A-2B are simplified block diagrams illustrating 16-slice chiplet devices according to examples of the present invention.

FIGS. 3A-3B are simplified block diagrams illustrating slice devices according to examples of the present invention.

FIG. 4 is a simplified block diagram illustrating an in-memory-compute (IMC) module according to an example of the present invention.

FIG. 5A is a simplified block flow diagram illustrating numerical formats of the data being processed in a slice device according to an example of the present invention.

FIG. 5B is a simplified diagram illustrating example numerical formats.

FIG. 6 is a simplified block diagram of a transformer architecture.

FIG. 7A is a simplified block diagram illustrating a column blocking converter apparatus according to an example of the present invention.

FIG. 7B is a simplified block diagram illustrating a column blocking converter apparatus according to an example of the present invention.

FIG. 8A is a simplified flow diagram illustrating a method of operating a column blocking apparatus according to an example of the present invention.

FIG. 8B is a simplified flow diagram illustrating a method of operating a column blocking apparatus according to an example of the present invention.

FIG. 9 is a simplified block flow diagram illustrating a mapping process between a transformer and an AI accelerator apparatus according to an example of the present invention.

FIG. 10A is a simplified diagram illustrating a matrix compute apparatus according to an example of the present invention.

FIG. 10B is a simplified diagram illustrating a method of operating a matrix compute apparatus according to an example of the present invention.

### DETAILED DESCRIPTION OF THE INVENTION

The present invention relates generally to integrated circuit (IC) devices and artificial intelligence (AI) systems. More particularly, the present invention relates to methods and device structures for accelerating computing workloads in transformer-based neural network models (a.k.a. transformers). These methods and structures can be used in machine/deep learning applications such as natural language processing (NLP), computer vision (CV), and the like. Merely by way of example, the invention has been applied to AI accelerator apparatuses and chiplet devices configured to perform high throughput operations for NLP.

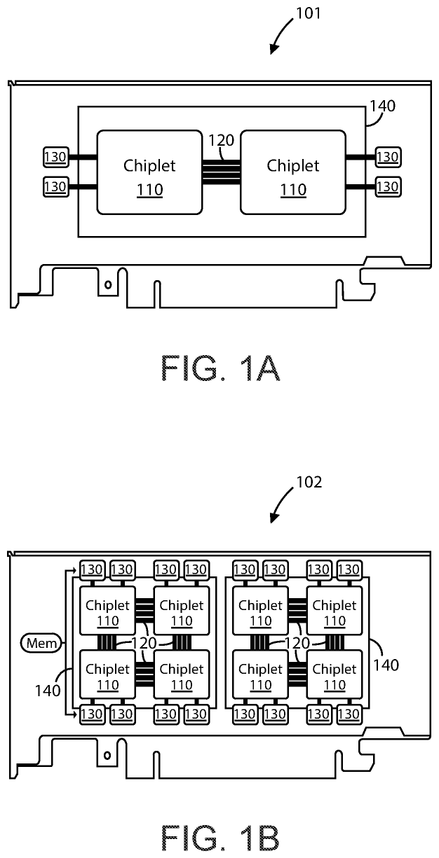

Currently, the vast majority of NLP models are based on the transformer model, such as the bidirectional encoder representations from transformers (BERT) model, BERT Large model, and generative pre-trained transformer (GPT) models such as GPT-2 and GPT-3, etc. However, these transformers have very high compute and memory requirements. According to an example, the present invention provides for an apparatus using chiplet devices that are configured to accelerate transformer computations for AI applications. Examples of the AI accelerator apparatus are shown in FIGS. 1A and 1B.

FIG. 1A illustrates a simplified AI accelerator apparatus 101 with two chiplet devices 110. As shown, the chiplet devices 110 are coupled to each other by one or more die-to-die (D2D) interconnects 120. Also, each chiplet device 110 is coupled to a memory interface 130 (e.g., static random access memory (SRAM), dynamic random access memory (DRAM), synchronous dynamic RAM (SDRAM), or the like). The apparatus 101 also includes a substrate member 140 that provides mechanical support to the chiplet devices 110 that are configured upon a surface region of the substrate member 140. The substrate can include interposers, such as a silicon interposer, glass interposer, organic interposer, or the like. The chiplets can be coupled to one or more interposers, which can be configured to enable communication between the chiplets and other components (e.g., serving as a bridge or conduit that allows electrical signals to pass between internal and external elements).

FIG. 1B illustrates a simplified AI accelerator apparatus 102 with eight chiplet devices 110 configured in two groups of four chiplets on the substrate member 140. Here, each chiplet device 110 within a group is coupled to other chiplet devices by one or more D2D interconnects 120. Apparatus 102 also shows a DRAM memory interface 130 coupled to each of the chiplet devices 110. The DRAM memory interface 130 can be coupled to one or more memory modules, represented by the “Mem” block.

As shown, the AI accelerator apparatuses 101 and 102 are embodied in peripheral component interconnect express (PCIe) card form factors, but the AI accelerator apparatus can be configured in other form factors as well. These PCIe card form factors can be configured in a variety of dimensions (e.g., full height, full length (FHFL); half height, half length (HHHL), etc.) and mechanical sizes (e.g., 1×, 2×, 4×, 16×, etc.). In an example, one or more substrate members 140, each having one or more chiplets, are coupled to a PCIe card. Those of ordinary skill in the art will recognize other variations, modifications, and alternatives to these elements and configurations of the AI accelerator apparatus.

Embodiments of the AI accelerator apparatus can implement several techniques to improve performance (e.g., computational efficiency) in various AI applications. The AI accelerator apparatus can include digital in-memory-compute (DIMC) to integrate computational functions and memory fabric. Algorithms for the mapper, numerics, and sparsity can be optimized within the compute fabric. And, use of chiplets and interconnects configured on organic interposers can provide modularity and scalability.

According to an example, the present invention implements chiplets with in-memory-compute (IMC) functionality, which can be used to accelerate the computations required by the workloads of transformers. The computations for training these models can include performing a scaled dot-product attention function to determine a probability distribution associated with a desired result in a particular AI application. In the case of training NLP models, the desired result can include predicting subsequent words, determining contextual word meaning, translating to another language, etc.

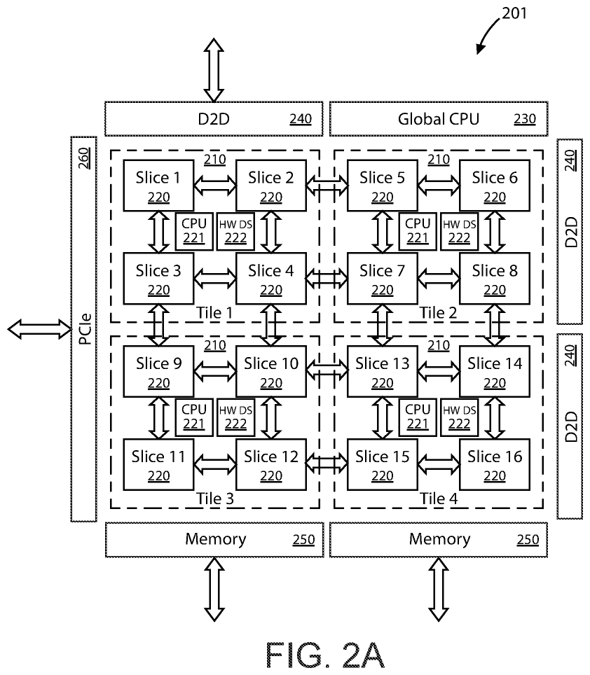

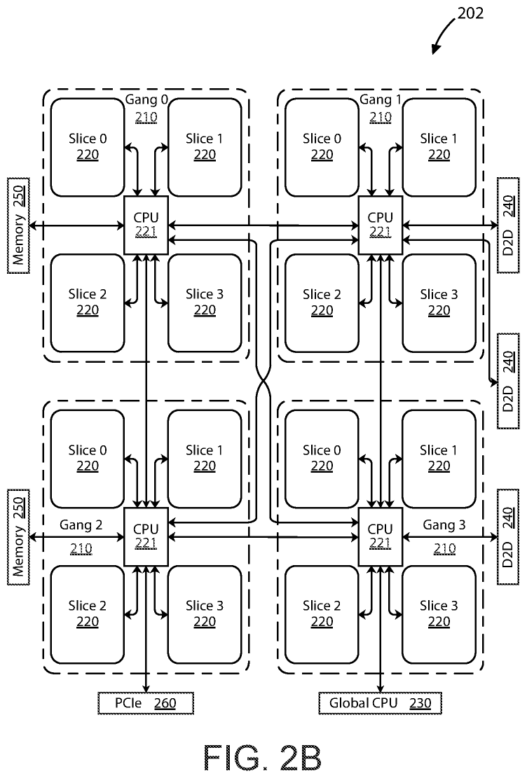

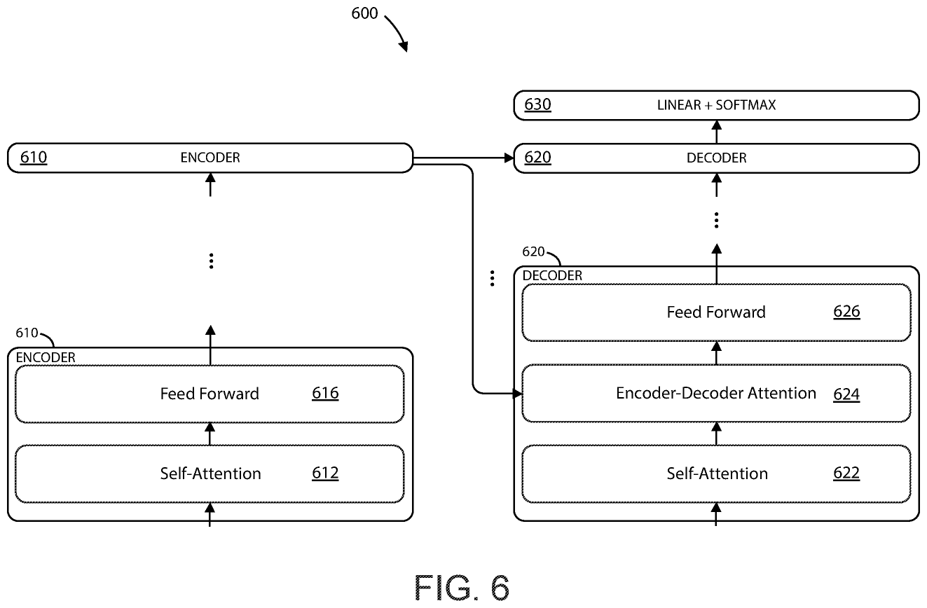

The chiplet architecture can include a plurality of slice devices (or slices) controlled by a central processing unit (CPU) to perform the transformer computations in parallel. Each slice is a modular IC device that can process a portion of these computations. The plurality of slices can be divided into tiles/gangs (i.e., subsets) of one or more slices with a CPU coupled to each of the slices within the tile. This tile CPU can be configured to perform transformer computations in parallel via each of the slices within the tile. A global CPU can be coupled to each of these tile CPUs and be configured to perform transformer computations in parallel via all of the slices in one or more chiplets using the tile CPUs. Further details of the chiplets are discussed in reference to FIGS. 2A-5B, while transformers are discussed in reference to FIGS. 6-9.

FIG. 2A is a simplified block diagram illustrating an example configuration of a 16-slice chiplet device 201. In this case, the chiplet 201 includes four tile devices 210, each of which includes four slice devices 220, a CPU 221, and a hardware dispatch (HW DS) device 222. In a specific example, these tiles 210 are arranged in a symmetrical manner. As discussed previously, the CPU 221 of a tile 210 can coordinate the operations performed by all slices within the tile. The HW DS 222 is coupled to the CPU 221 and can be configured to coordinate control of the slices 220 in the tile 210 (e.g., to determine which slice in the tile processes a target portion of transformer computations). In a specific example, the CPU 221 can be a reduced instruction set computer (RISC) CPU, or the like. Further, the CPU 221 can be coupled to a dispatch engine, which is configured to coordinate control of the CPU 221 (e.g., to determine which portions of transformer computations are processed by the particular CPU).

The CPUs 221 of each tile 210 can be coupled to a global CPU via a global CPU interface 230 (e.g., buses, connectors, sockets, etc.). This global CPU can be configured to coordinate the processing of all chiplet devices in an AI accelerator apparatus, such as apparatuses 101 and 102 of FIGS. 1A and 1B, respectively. In an example, a global CPU can use the HW DS 222 of each tile to direct each associated CPU 221 to perform various portions of the transformer computations across the slices in the tile. Also, the global CPU can be a RISC processor, or the like. The chiplet 201 also includes D2D interconnects 240 and a memory interface 250, both of which are coupled to each of the CPUs 221 in each of the tiles. In an example, the D2D interconnects can be configured with single-ended signaling. The memory interface 250 can include one or more memory buses coupled to one or more memory devices (e.g., DRAM, SRAM, SDRAM, or the like).

Further, the chiplet 201 includes a PCIe interface/bus 260 coupled to each of the CPUs 221 in each of the tiles. The PCIe interface 260 can be configured to communicate with a server or other communication system. In the case of a plurality of chiplet devices, a main bus device is coupled to the PCIe bus 260 of each chiplet device using a master chiplet device (e.g., main bus device also coupled to the master chiplet device). This master chiplet device is coupled to each other chiplet device using at least the D2D interconnects 240. The master chiplet device and the main bus device can be configured overlying a substrate member (e.g., same substrate as chiplets or separate substrate). An apparatus integrating one or more chiplets can also be coupled to a power source (e.g., configured on-chip, configured in a system, or coupled externally) and can be configured and operable to a server, network switch, or host system using the main bus device. The server apparatus can also be one of a plurality of server apparatuses configured for a server farm within a data center, or other similar configuration.

In a specific example, an AI accelerator apparatus configured for GPT-3 can incorporate eight chiplets (similar to apparatus 102 of FIG. 1B). The chiplets can be configured with D2D 16×16 Gb/s interconnects, 32-bit LPDDRS 6.4 Gb/s memory modules, and 16 lane PCIe Gen 5 PHY NRZ 32 Gb/s/lane interface. LPDDRS (16×16 GB) can provide the necessary capacity, bandwidth and low power for large scale NLP models, such as quantized GPT-3. Of course, there can be other variations, modifications, and alternatives.

FIG. 2B is a simplified block diagram illustrating an example configuration of a 16-slice chiplet device 202. Similar to chiplet 201, chiplet 202 includes four gangs 210 (or tiles), each of which includes four slice devices 220 and a CPU 221. As shown, the CPU 221 of each gang/tile 210 is coupled to each of the slices 220 and to each other CPU 221 of the other gangs/tiles 210. In an example, the tiles/gangs serve as neural cores, and the slices serve as compute cores. With this multi-core configuration, the chiplet device can be configured to take and run several computations in parallel. The CPUs 221 are also coupled to a global CPU interface 230, D2D interconnects 240, a memory interface 250, and a PCIe interface 260. As described for FIG. 2A, the global CPU interface 230 connects to a global CPU that controls all of the CPUs 221 of each gang 210.

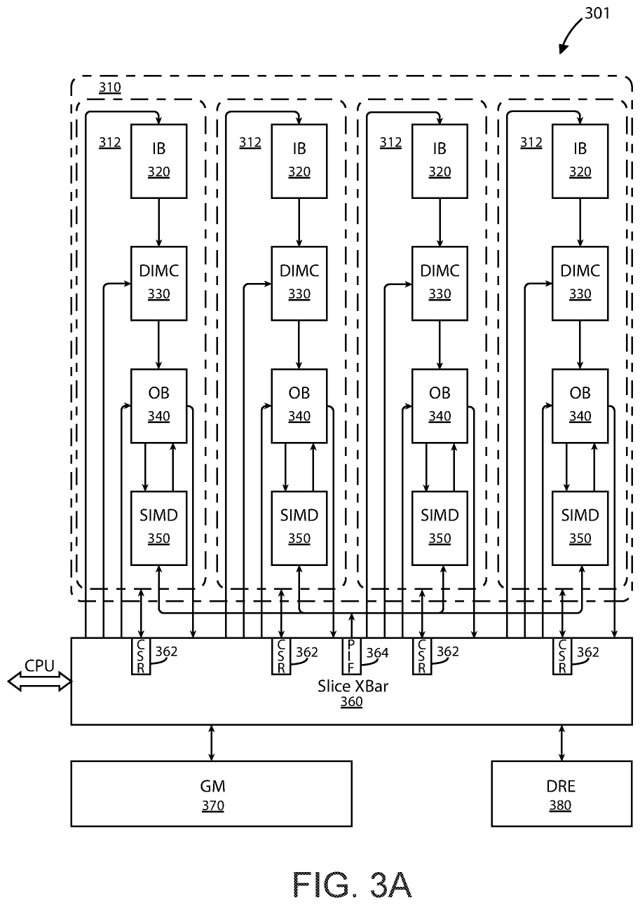

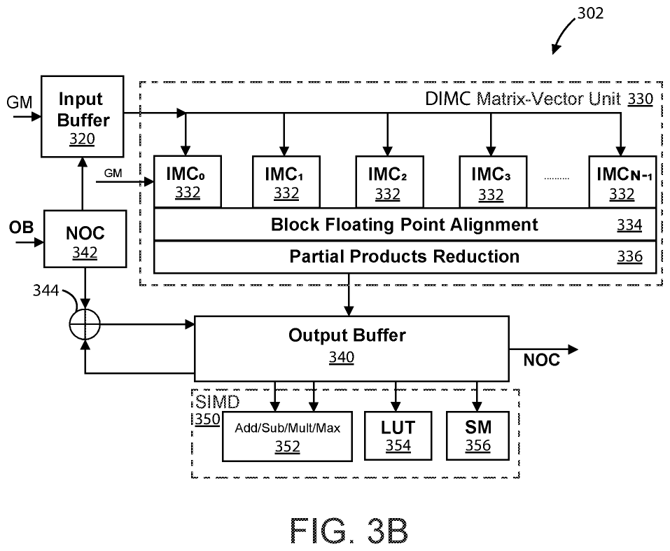

FIG. 3A is a simplified block diagram illustrating an example slice device 301 of a chiplet. For the 16-slice chiplet example, slice device 301 includes a compute core 310 having four compute paths 312, each of which includes an input buffer (TB) device 320, a digital in-memory-compute (DIMC) device 330, an output buffer (OB) device 340, and a Single Instruction, Multiple Data (SIMD) device 350 coupled together. Each of these paths 312 is coupled to a slice cross-bar/controller 360, which is controlled by the tile CPU to coordinate the computations performed by each path 312.

In an example, the DIMC is coupled to a clock and is configured within one or more portions of each of the plurality of slices of the chiplet to allow for high throughput of one or more matrix computations provided in the DIMC such that the high throughput is characterized by 512 multiply accumulates per a clock cycle. In a specific example, the clock coupled to the DIMC is a second clock derived from a first clock (e.g., chiplet clock generator, AI accelerator apparatus clock generator, etc.) configured to output a clock signal of about 0.5 GHz to 4 GHz; the second clock can be configured at an output rate of about one half of the rate of the first clock. The DIMC can also be configured to support a block structured sparsity (e.g., imposing structural constraints on weight patterns of a neural networks like a transformer).

In an example, the SIMD device 350 is a SIMD processor coupled to an output of the DIMC. The SIMD 350 can be configured to process one or more non-linear operations and one or more linear operations on a vector process. The SIMD 350 can be a programmable vector unit or the like. The SIMD 350 can also include one or more random-access memory (RAM) modules, such as a data RAM module, an instruction RAM module, and the like.

In an example, the slice controller 360 is coupled to all blocks of each compute path 312 and also includes a control/status register (CSR) 362 coupled to each compute path. The slice controller 360 is also coupled to a memory bank 370 and a data reshape engine (DRE) 380. The slice controller 360 can be configured to feed data from the memory bank 370 to the blocks in each of the compute paths 312 and to coordinate these compute paths 312 by a processor interface (PIF) 364. In a specific example, the PIF 364 is coupled to the SIMD 350 of each compute path 312.

Further details for the compute core 310 are shown in FIG. 3B. The simplified block diagram of slice device 302 includes an input buffer 320, a DIMC matrix vector unit 330, an output buffer 340, a network on chip (NoC) device 342, and a SIMD vector unit 350. The DIMC unit 330 includes a plurality of in-memory-compute (IMC) modules 332 configured to compute a Scaled Dot-Product Attention function on input data to determine a probability distribution, which requires high-throughput matrix multiply-accumulate operations.

These IMC modules 332 can also be coupled to a block floating point alignment module 334 and a partial products reduction module 336 for further processing before outputting the DIMC results to the output buffer 540. In an example, the input buffer 320 receives input data (e.g., data vectors) from the memory bank 370 (shown in FIG. 3A) and sends the data to the IMC modules 332. The IMC modules 332 can also receive instructions from the memory bank 370 as well.

In addition to the details discussed previously, the SIMD 350 can be configured as an element-wise vector unit. The SIMD 350 can include a computation unit 352 (e.g., add, subtract, multiply, max, etc.), a look-up table (LUT) 354, and a state machine (SM) module 356 configured to receive one or more outputs from the output buffer 340.

The NoC device 342 is coupled to the output buffer 340 configured in a feedforward loop via shortcut connection 344. Also, the NoC device 342 is coupled to each of the slices and is configured for multicast and unicast processes. More particularly, the NoC device 342 can be configured to connect all of the slices and all of the tiles, multi-cast input activations to all of the slices/tiles, and collect the partial computations to be unicast for a specially distributed accumulation.

Considering the previous eight-chiplet AI accelerator apparatus example, the input buffer can have a capacity of 64 KB with 16 banks and the output buffer can have a capacity of 128 KB with 16 banks. The DIMC can be an 8-bit block have dimensions 64×64 (eight 64×64 IMC modules) and the NoC can have a size of 512 bits. The computation block in the SIMD can be configured for 8-bit and 32-bit integer (int) and unsigned integer (uint) computations, as well as floating point computations, such as IEEE 854 float16 or float32. These slice components can vary depending on which transformer the AI accelerator apparatus will serve.

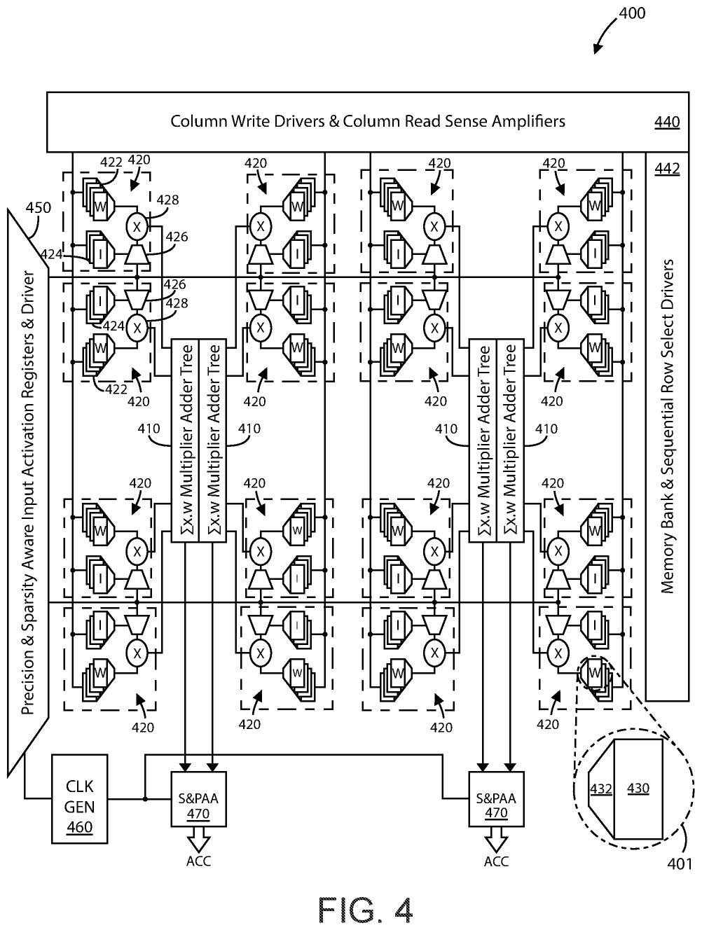

FIG. 4 is a simplified block diagram illustrating an example IMC module 700. As shown, module 700 includes one or more computation tree blocks 410 that are configured to perform desired computations on input data from one or more read-write blocks 420. Each of these read-write blocks 420 includes one or more first memory-select units 422 (also denoted as “W”), one or more second memory-select units 424 (also denoted as “I”), an activation multiplexer 426, and an operator unit 428. The first memory-select unit 422 provides an input to the operator unit 428, while the second memory-select unit 424 controls the activation multiplexer 426 that is also coupled to the operator unit 428. In the case of multiply-accumulate operations, the operator unit 428 is a multiplier unit and the computation tree blocks 410 are multiplier adder tree blocks (i.e., Σx·w).

As shown in close-up 401, each of the memory-select units 422, 424 includes a memory cell 430 (e.g., SRAM cell, or the like) and a select multiplexer 432. Each of the memory-select units 422, 424 is coupled to a read-write controller 440, which is also coupled to a memory bank/driver block 442. In an example, the read-write controller 440 can be configured with column write drivers and column read sense amplifiers, while the memory bank/driver block 432 can configured with sequential row select drivers.

An input activation controller 450 can be coupled to the activation multiplexer 426 each of the read-write blocks 420. The input activation controller 450 can include precision and sparsity aware input activation register and drivers. The operator unit 428 receives the output of the first memory-select unit 422 and receives the output of this block 450 through the activation multiplexer 426, which is controlled by the output of the second memory-select unit 424. The output of the operator unit 428 is then fed into the computation tree block 410.

The input activation block 450 is also coupled to a clock source/generator 460. As discussed previously, the clock generator 460 can produce a second clock derived from a first clock configured to output a clock signal of about 0.5 GHz to 4 GHz; the second clock can be configured at an output rate of about one half of the rate of the first clock. The clock generator 460 is coupled to one or more sign and precision aware accumulators 470, which are configured to receive the output of the computation tree blocks 410. In an example, an accumulator 470 is configured to receive the outputs of two computation tree blocks 410. Example output readings of the IMC are shown in FIGS. 13A-13C.

Referring back to the eight-chiplet AI accelerator apparatus example, the memory cell can be a dual bank 2×6T SRAM cell, and the select multiplexer can be an 8T bank select multiplexer. In this case, the memory bank/driver block 442 includes a dual-bank SRAM bank. Also, the read/write controller can include 64 bytes of write drivers and 64 bytes of read sense amplifiers. Those of ordinary skill in the art will recognize other variations, modifications, and alternatives to these IMC module components and their configurations.

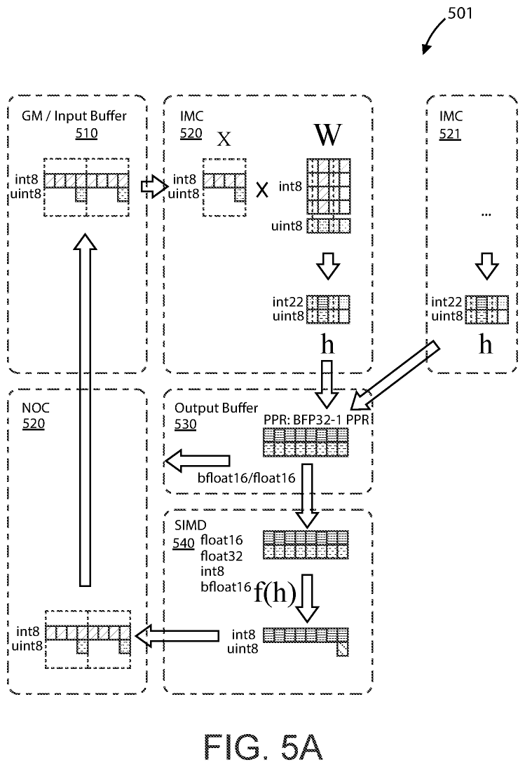

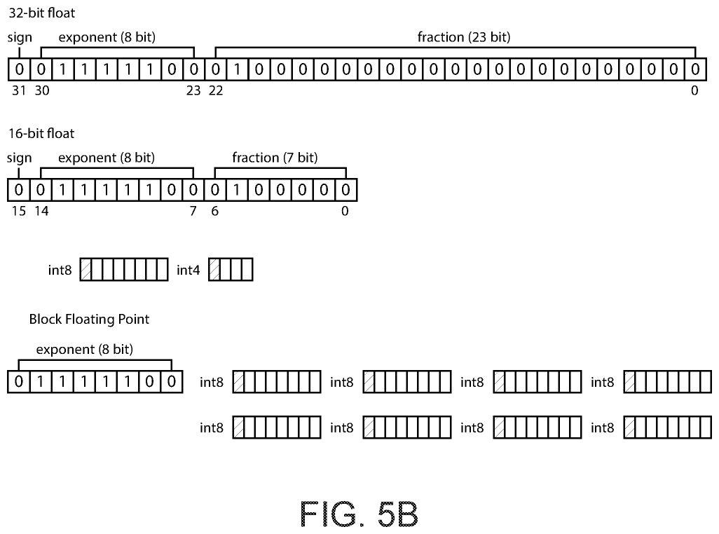

FIG. 5A is a simplified block flow diagram illustrating example numerical formats of the data being processed in a slice. Diagram 501 shows a loop with the data formats for the GM/input buffer 510, the IMC 520, the output buffer 530, the SIMD 540, and the NoC 550, which feeds back to the GM/input buffer 510. The IMC block 520 shows the multiply-accumulate operation (Σx·w). Additionally, the format for the data from IMC 532 flows to the output buffer 530 as well. In this example, the numerical formats include integer (int), floating point (float), and block floating point (BFP) of varying lengths.

FIG. 5B is a simplified diagram illustrating certain numerical formats, including certain formats shown in FIG. 5A. Block floating point numerics can be used to address certain barriers to performance. Training of transformers is generally done in floating point, i.e., 32-bit float or 16-bit float, and inference is generally done in 8-bit integer (“int8”). With block floating point, an exponent is shared across a set of mantissa significant values (see diagonally line filled blocks of the int8 vectors at the bottom of FIG. 5B), as opposed to floating point where each mantissa has a separate exponent (see 32-bit float and 16-bit float formats at the top of FIG. 5A). The method of using block floating point numerical formats for inference can exhibit the efficiency of fixed point without the accuracy and deployment problems of integer arithmetic, and can also allow for use of a smaller mantissa, e.g., 4-bit integer (“int4”) while retaining accuracy. Further, by using the block floating point format (e.g., for activation, weights, etc.) and sparsity, the inference of the training models can be accelerated for better performance. Those of ordinary skill in the art will recognize other variations, modifications, and alternatives to these numerical formats used to process transformer workloads.

FIG. 6 illustrates a simplified transformer architecture 600. The typical transformer can be described as having an encoder stack configured with a decoder stack, and each such stack can have one or more layers. Within the encoder layers 610, a self-attention layer 612 determines contextual information while encoding input data and feeds the encoded data to a feed-forward neural network 616. The encoder layers 610 process an input sequence from bottom to top, transforming the output into a set of attention vectors K and V. The decoder layers 620 also include a corresponding self-attention layer 622 and feed-forward neural network 626, and can further include an encoder-decoder attention layer 624 uses the attention vectors from the encoder stack that aid the decoder in further contextual processing. The decoder stack outputs a vector of floating points (as discussed for FIG. 5B), which is fed to linear and softmax layers 630 to project the output into a final desired result (e.g., desired word prediction, interpretation, or translation). The linear layer is a fully-connected neural network that projects the decoder output vector into a larger vector (i.e., logits vector) that contains scores associated with all potential results (e.g., all potential words), and the softmax layer turns these scores into probabilities. Based on the probability output, the projected word meaning may be chosen based on the highest probability or by other derived criteria depending on the application.

Transformer model variations include those based on just the decoder stack (e.g., transformer language models such as GPT-2, GPT-3, etc.) and those based on just the encoder stack (e.g., masked language models such as BERT, BERT Large, etc.). Transformers are based on four parameters: sequence length (S) (i.e., number of tokens), number of attention heads (A), number of layers (L), and embedding length (H). Variations of these parameters are used to build practically all transformer-based models today. Embodiments of the present invention can be configured for any similar model types.

A transformer starts as untrained and is pre-trained by exposure to a desired data set for a desired learning application. Transformer-based language models are exposed to large volumes of text (e.g., Wikipedia) to train language processing functions such as predicting the next word in a text sequence, translating the text to another language, etc. This training process involves converting the text (e.g., words or parts of words) into token IDs, evaluating the context of the tokens by a self-attention layer, and predicting the result by a feed forward neural network.

The self-attention process includes (1) determining query (Q), key (K), and value (V) vectors for the embedding of each word in an input sentence, (2) calculating a score for from the dot product of Q and K for each word of the input sentence against a target word, (3) dividing the scores by the square root of the dimension of K, (4) passing the result through a softmax operation to normalize the scores, (5) multiplying each V by the softmax score, and (6) summing up the weighted V vectors to produce the output. Note that the value matrix V becomes the weight matrix for matrix multiplication with softmax attention matrix; in the context of block floating point numerics, this requires a column blocking converter for V as described below.

Many things impact the performance of such transformer architectures. The softmax function tends to be the critical path of the transformer layers (and has been difficult to accelerate in hardware). Requirements for overlapping the compute, SIMD operations and NoC transfers also impacts performance. Further, efficiency of NoC, SIMD, and memory bandwidth utilization is important as well.

Different techniques can be applied in conjunction with the AI accelerator apparatus and chiplet device examples to improve performance, such as quantization, sparsity, knowledge distillation, efficient tokenization, and software optimizations. Supporting variable sequence length (i.e., not requiring padding to the highest sequence lengths) can also reduce memory requirements. Other techniques can include optimizations of how to split self-attention among slices and chips, moving layers and tensors between the slices and chips, and data movement between layers and FC matrices.

According to an example, the present invention provides for an AI accelerator apparatus (such as shown in FIGS. 1A and 1B) coupled to an aggregate of transformer devices (e.g., BERT, BERT Large, GPT-2, GPT-3, or the like). In a specific example, this aggregate of transformer devices can include a plurality of transformers configured in a stack ranging from three to N layers, where N is an integer up to 128.

In an example, each of the transformers is configured within one or more DIMCs such that each of the transformers comprises a plurality of matrix multipliers including QKV matrices configured for an attention layer of a transformer followed by three fully-connected matrices (FC). In this configuration, the DIMC is configured to accelerate the transformer and further comprises a dot product of Q K^{T} followed by a softmax (Q K^{T}/square root (dₖ))V. In an example, the AI accelerator apparatus also includes a SIMD device (as shown in FIGS. 3A and 3B) configured to accelerate a computing process of the softmax function.

Using a transformer like BERT Large, NLP requires very high compute (e.g., five orders of magnitude higher than CV). For example, BERT Large requires 5.6 giga-multiply-accumulate operations per second (“GMACs”) per transformer layer. Thus, the NLP inference challenge is to deliver this performance at the lowest energy consumption.

Although the present invention is discussed in the context of a BERT Large transformer for NLP applications, those of ordinary skill in the art will recognize variations, modifications, and alternatives. The particular embodiments shown can also be adapted to other transformer-based models and other AI/machine learning applications.

As discussed previously, block floating point (BFP) formats are important for efficient hardware acceleration of matrix multiplication operations in deep neural network inference. Matrix weights are often blocked along the columns, while the activations are often blocked along the rows. Thus, BFP numerics enable an efficient integer arithmetic implementation of matrix multiplication while maintaining a large dynamic range. After a matrix multiplication, the activation row vector dot product with the weight column vector is accumulated into a floating point (FP) format (e.g., FP32, FP16, etc.) and stored into an output buffer as a matrix tile (e.g., 64×64 tile of FP16). We may also use BFP32-1, with 24 bit mantissa in 2's complement, and 8 bit exponent in 2's complement, as an equivalent format to FP32 for accumulation of partial products.

The output buffer memory load/store is typically implemented row-wise, which is convenient for the typical case of row-wise BFP blocking to generate the activations for the next matrix multiplication. However, there are cases in which the output of a matrix multiplication is used as a weight matrix for a subsequent matrix multiplication (e.g., matrix multiplication with a value matrix for an attention function in a BERT encoder model), which requires storing the data from the output buffer in a column blocking configuration. In such cases, blocking across the columns poses a challenge when the memory load/store is characterized by a row-wise storage configuration because the output converter can only read data one row at a time.

According to an example, the present invention provides a column blocking converter apparatus and method for converting data from a first format in a row blocking configuration to a second format in a column blocking configuration. The column blocking apparatus can be configured as an IC for an AI accelerator apparatus, such as the examples AI accelerator ICs described previously.

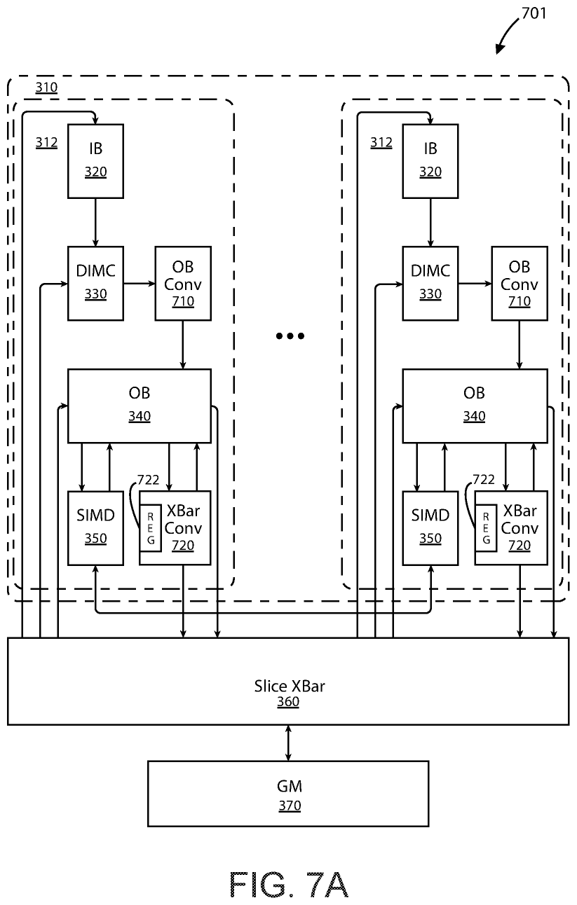

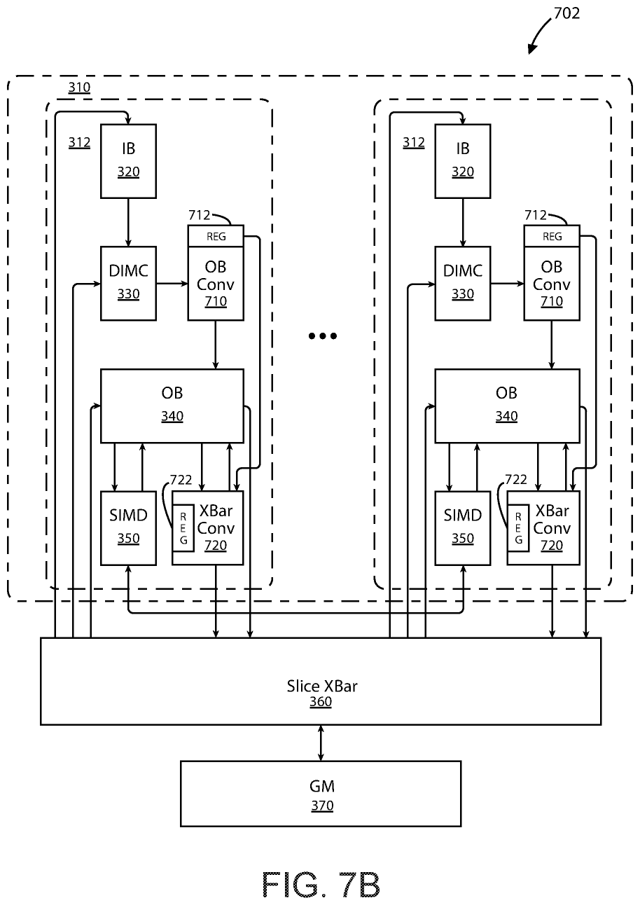

FIGS. 7A and 7B are simplified block diagrams illustrating column blocking converter apparatuses 701/702 according to examples of the present invention. As shown, the apparatuses 701/702 are similar to slice device 301 shown in FIG. 3A. Any shared reference numerals between these figures refer to the same elements as described previously. Here, FIGS. 7A and 7B only show two compute paths 312 in the compute core 310, however there can be additional compute paths 312 depending upon the application.

The apparatus 701 of FIG. 7A can include a compute path 312 with an input buffer (IB) device 320, a compute device 330, an output buffer (OB) 340 device. The IB device 320 is coupled to the compute device 330 and is configured to receive a plurality of matrix inputs. The compute device 330 is coupled to the OB device 340 and is configured to perform a plurality of matrix computations on the plurality of matrix inputs. In a specific example, the compute device 330 can be a digital in-memory compute (DIMC) device 330 performing a softmax function, as discussed previously. In this case, the OB device 340 can be characterized by a row-wise storage configuration and can be configured to store, in a first format, a plurality of matrix outputs resulting from the plurality of matrix outputs resulting from the plurality of matrix computations.

An OB converter device 710 can be coupled between the compute device 330 and the OB device 340. This OB converter device 710 can be configured to store the plurality of matrix outputs in the first format within the OB device 340. As shown, the OB converter device 710 is configured separately from the OB device 340, however, the OB converter device 710 can also be configured within the OB device 340. These configurations can be implemented as an inline column blocking converter apparatus.

A crossbar device 360 is coupled to the IB device 320, the compute device 330, and the OB device 340. A crossbar converter device 720 is also coupled to the OB device 340 and is configured to convert the plurality of matrix outputs from the first format to a second format using a max exponent value and a mantissa value determined for each of the plurality of matrix outputs, resulting in a plurality of converted matrix outputs. As shown, the crossbar converter device 720 is configured within the compute path 312; however, the crossbar converter device 720 can also be configured within the crossbar device 360.

Further, a memory device 370 is coupled to the crossbar device 360. This memory device is configured to store the plurality of converted matrix outputs, in the second format and in a column blocking configuration, using the max exponent values and the mantissa values. The first format can be a floating point (FP) format, while the second format can be a block floating point (BFP) format. In a specific example, the first format is an FP16 format, the second format is a BFP format with a block size of 64 elements, mantissa bit width of 8 bits, and a shared exponent of 8 bits (BFP16-64 format). In this case, the plurality of matrix outputs can be characterized by a 64.64 byte tile of mantissas and a 64 byte row of shared exponents. This embodiment of the invention encompasses an efficient algorithm and hardware architecture for a column blocking converter for converting an FP16 tile of 64×64 elements stored in an output buffer to a BFP16-64 tile blocked along the columns.

In an example, the crossbar converter device 720 includes a max exponent register 722 configured to store the max exponent values of each of the plurality of matrix outputs. The OB device 340 and the converter device can be configured together to determine the max exponent value of each of the plurality of matrix outputs in a first row-by-row process, to determine the mantissa value of each of the plurality of matrix outputs in a second row-by-row process, and to store the max exponent values and the mantissa values in the memory device. The max exponent register 722 can be used in the first row-by-row process to store the max exponent values.

In a specific example, the crossbar converter device 720 is configured to perform a shifting process and a rounding process on the mantissa value for each of the plurality of matrix outputs during the second row-by-row process. The crossbar device 360 can be configured to write the mantissa values to the memory device 370 after each row in the second row-by-row process. Further, the crossbar device 360 can be configured to write the max exponent values to the memory device 370 after the second row-by-row process. The crossbar converter device 720 can be coupled to the OB device 340 in a feedback configuration to perform the first and second row-by-row processes.

Compared to FIG. 7A, FIG. 7B shows an alternative device architecture for a column blocking converter apparatus 702 in which the OB converter device 710 also includes a max exponent register 712 that is coupled to the crossbar converter device 720. Instead of the crossbar converter device 720, the OB converter device 710 can be configured to determine the max exponent value of each of the plurality of matrix outputs in the first row-by-row process and to store the max exponent values in this first max exponent register 712. Then, the crossbar converter device 720 can be configured to store the max exponent values from the first max exponent register 712 in its second max exponent register 722 and to determine the mantissa value for each of the plurality of the matrix outputs from the OB device in the second row-by-row process.

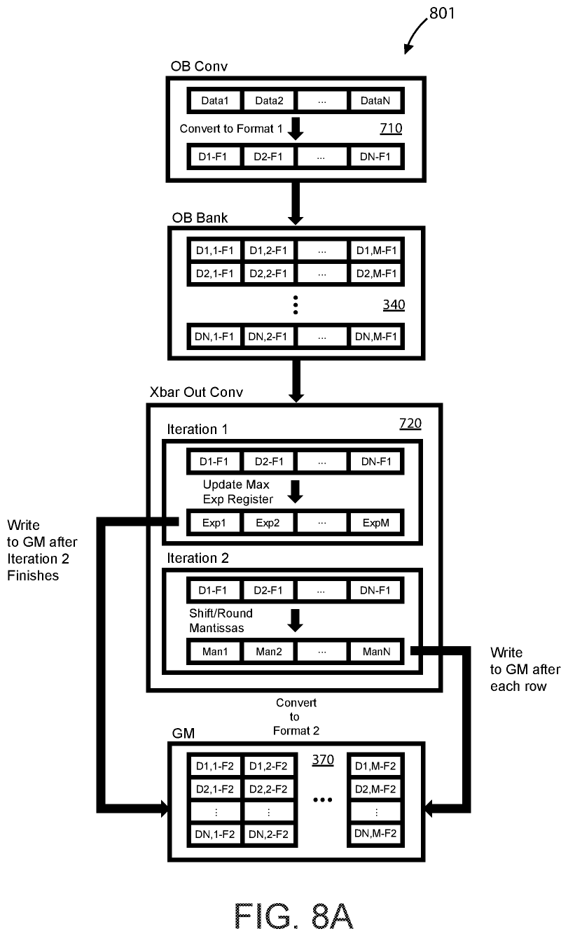

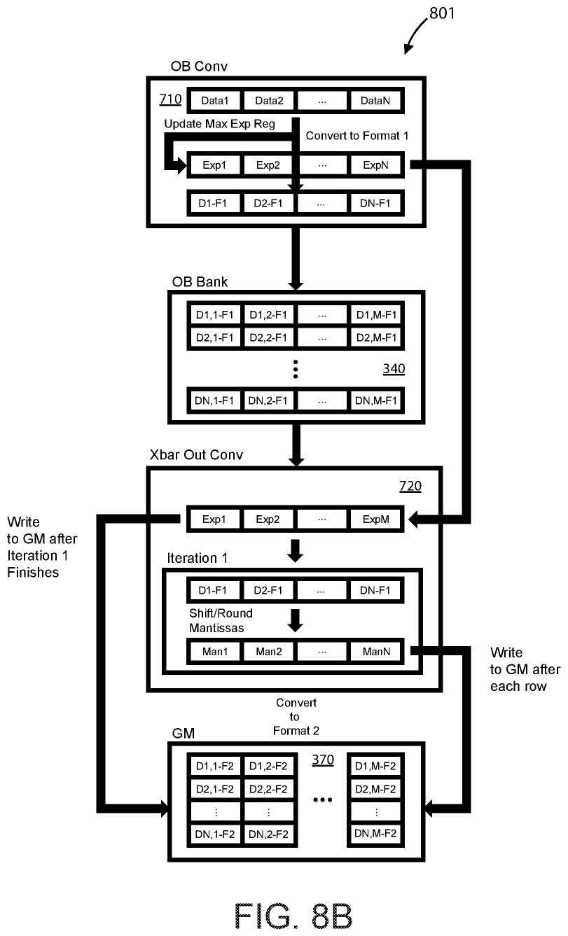

Similar to the first architecture, the crossbar converter device 720 can be configured to perform the shifting process and the rounding process on the mantissa value for each of the plurality of matrix outputs. And, the crossbar device 360 can be configured to write the max exponent values to the memory device 370 after the second row-by-row process. Further details of the processes performed by the OB converter device 710 and the crossbar converter device 720 are discussed with reference to FIGS. 8A and 8B.

FIG. 8A is a simplified flow diagram illustrating a method 801 of operating a column blocking converter apparatus according to an example of the present invention. This method corresponds to the apparatus 701 shown in FIG. 7A in which the crossbar converter device 720 is configured to perform the first and second row-by-row processes. As shown, the method 801 begins with receiving the plurality of matrix outputs (a tile of N×M matrix outputs; where N and M are integers) at the OB converter 710. In an example, these matrix outputs are the results (each row denoted by “Data1” to “DataN”) from matrix multiplications (e.g., for a softmax function) that the OB converter 710 converts to a first format (denoted by “D1-F1” to “DN-F1”) and writes to the OB device/bank 340 (denoted by “DN,M-F1). Considering the 64×64 byte example, each of the 64 elements in a row is in a BFP32-1 format, which the OB converter 710 converts to an FP16 format.

Here, the crossbar converter device 720 reads the OB bank 340 to perform the first and second row-by-row processes to determine the max exponent and mantissa values, respectively. The crossbar converter device 720 reads each row of the data stored in the OB bank 340 one row at a time to determine the max exponent value of each entry and to update the max exponent register 722 (e.g., if expᵢ<reg_exp[i], then reg_exp[i]=expᵢ). In the 64×64 byte example, the converter device 720 reads in a row of 64 FP16 elements at a time. After all rows are processed, the max exponent register 722 contains the max exponent (denoted by “Exp1” to “ExpM”) for each column of the tile of data stored in the OB bank 340.

Then, the converter device 720 reads each row from the OB bank 340 again in the second row-by-row process to determine the mantissa values. For each of the OB bank entries, the converter device 720 can perform a shifting process and a rounding process to convert the mantissa values to a desired format (e.g., integer format or other numerical format). In the 64×64 byte example, the shifting and rounding processes can result in converting the mantissa values into an 8-bit integer (int8) format. After processing a row of mantissas (denoted by “Man1” to “ManN”), the processed data is sent to be written to the memory device 370. Once all rows are processed, the conversion of the mantissas to the second format (denoted by “DN,M-F2”) in the column blocking configuration is complete. With the max exponent register data sent afterwards, the memory device 370 will contain a contiguous block of data in which each column is in the second format. In the 64×64 byte matrix data example, the contiguous block is characterized by 65×64 bytes and each column is in a BFP16-64 format.

FIG. 8B is a simplified flow diagram illustrating a method 802 of operating a column blocking converter apparatus according to an example of the present invention. This method corresponds to the apparatus 702 shown in FIG. 7B in which the OB converter device 710 is configured to perform the first row-by-row process using its own max exponent register 712 and the crossbar converter device 720 is configured to perform the second row-by-row process. Using the same denotations as method 801, the method 802 begins with receiving the plurality of matrix outputs (a tile of matrix outputs) at the OB converter 710. In an example, the OB converter device 710 converts the outputs to a first format. After each row of data is converted to the first format, the OB converter device 710 also determines the max exponent value of each entry and updates the max exponent register 712 (e.g., if expᵢ<reg_exp[i], then reg_exp[i]=expᵢ). After all rows of the outputs are processed by the OB converter device 710, the max exponent register 712 contains the max exponent for each column of the tile. Considering the 64×64 byte example, each of the 64 elements in a row is in a BFP32-1 format (a 32 bit floating point format), which the OB converter 710 converts to an FP16 format (a 16 bit floating point format).

Then, the crossbar converter device 720 reads the max exponent data from the OB converter register 712 to its own max exponent register 722. Similar to method 801, the crossbar converter device 720 reads each row from the OB bank 340 in the second row-by-row process to determine the mantissa values. The converter device 720 also performs the shifting process and the rounding process to convert the mantissa values to a desired format (e.g., integer format or other numerical format). After processing a row of mantissas, the processed data is sent to be written to the memory device 370. Once all rows are processed, the conversion of the mantissas to the second format in the column blocking configuration is complete. With the max exponent register data sent afterwards, the memory device 370 will contain a contiguous block of data in which each column is in the second format. In the 64×64 byte matrix data example, the contiguous block is characterized by 65×64 bytes and each column is in a BFP16-64 format.

Although these examples are discussed with respect to the FP and BFP numerical formats, the column blocking converter apparatus and its method can be applied to the conversion of data from any first format to any second format that can be determined by corresponding exponent and mantissa values. There are also variations on computing the shared block exponent; for example, instead of the max exponent, it possible to use a percentile value.

Also, in cases that buffer memory load/store is implemented column-wise, the same techniques described herein can be used convert from a column-wise storage configuration to a row-wise storage configuration. Those of ordinary skill in the art will recognize other variations, modifications, and alternatives these blocking conversion methods and structures.

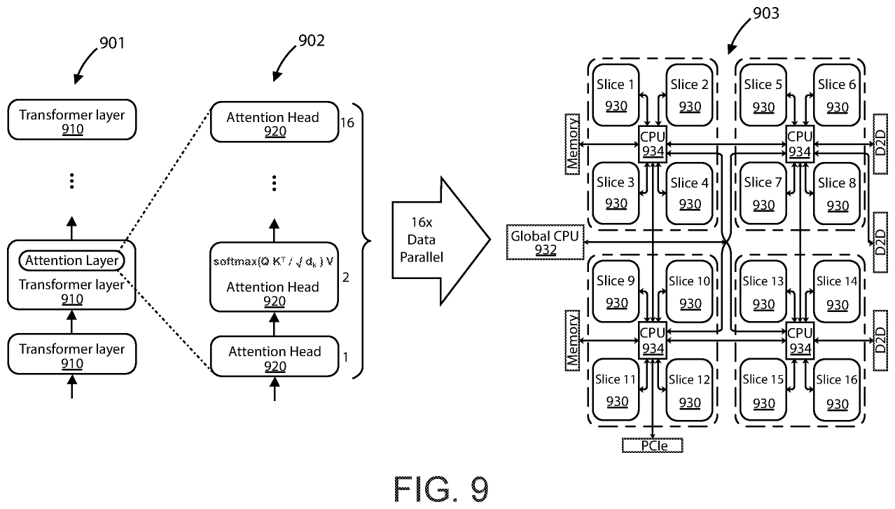

FIG. 9 is a simplified block flow diagram illustrating a mapping process between a transformer and an example AI accelerator apparatus. As shown, a transformer 901 includes a plurality of transformer layers 910, each having an attention layer 902. In this case, there are 16 attention heads 920 (e.g., BERT Large) computing the attention function as discussed previously. These 16 attention heads are mapped to 16 slices 930 of an AI accelerator apparatus 903 (similar to apparatuses 201 and 202) via global CPU 932 communicating to the tile CPUs 934.

According to an example, the present invention provides a method and device for data conversion in a matrix compute apparatus. In a specific example, the matrix compute apparatus can be configured as a multiply and accumulate (MAC) unit that serves as a key building block of the dot product and matrix multiplication hardware used to accelerate deep neural network inference applications, including the NLP workloads discussed previously. In such applications, there may be a need to handle more than one kind of data format. For example, efficient MAC implementations are often based on integer arithmetic, which support fixed point or block floating point (BFP) numerical formats. However, in certain applications, it is desirable for the MAC unit, or other matrix compute apparatus, to have the capability of handling floating point (FP) or brain floating point (Bfloat) numerical formats.

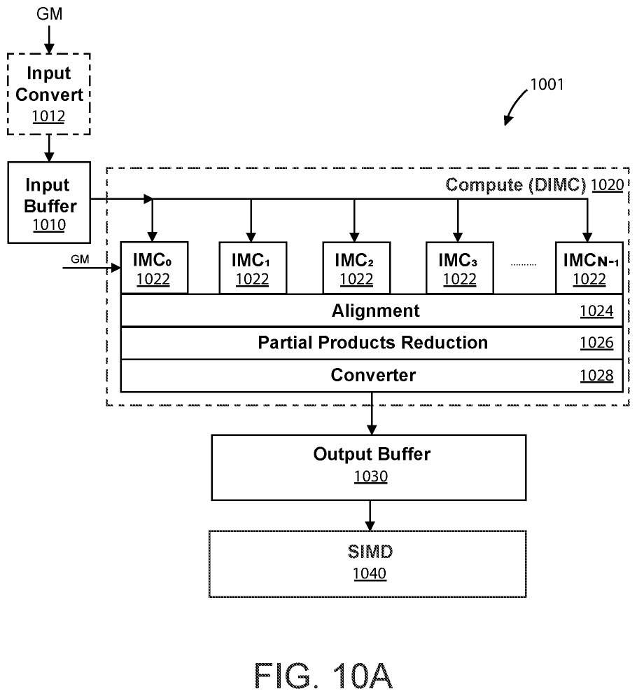

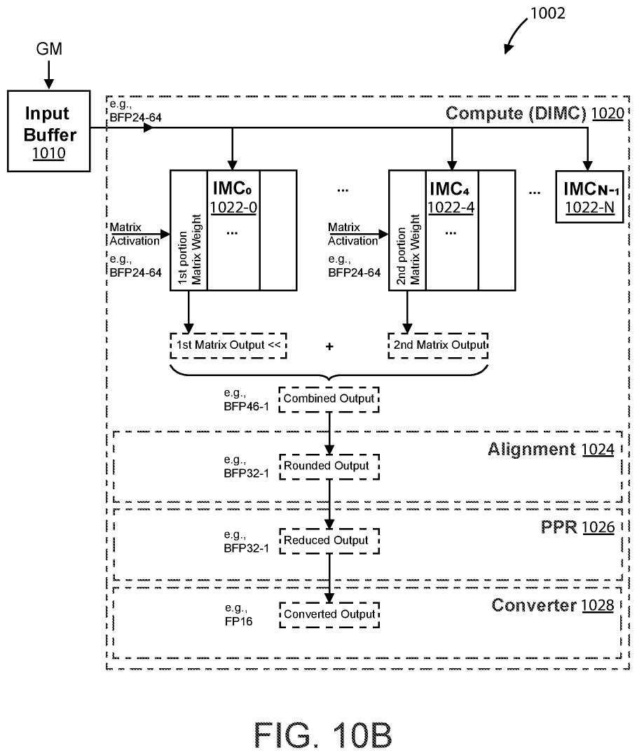

Thus, the present invention provides for a method and device to enable a matrix compute apparatus configured to process matrix data in a target format by segmenting the data and parallel processing the segmented data portions in the native format of the matrix compute apparatus. Merely by way of example, the present invention discusses the native format as an 8-bit integer (int8) format and the target format as a 16-bit floating point (FP16) format. Embodiments of the present matrix compute apparatus can be configured as an IC for an AI accelerator IC, such as the AI accelerator systems discussed previously. Further details are discussed below with reference to FIGS. 10A and 10B.

FIG. 10A is a simplified diagram illustrating a matrix compute apparatus 1001 according to an example of the present invention. As shown, this apparatus 1001 can be configured similarly to the example slice device 302 of FIG. 3B with an input buffer (IB) 1010 device, a compute device 1020 (e.g., DIMC device) coupled to the IB device 1010, and an output buffer (OB) device 1030 coupled to the compute device 1020. Also, a Single Instruction, Multiple Data (SIMD) device 1040 can be coupled to the OB device 1030. Similar to slice device 302, this apparatus 1001 can be configured within a chiplet device (see examples in FIGS. 2A and 2B) that is part of an AI accelerator system (see examples in FIGS. 1A and 1B).

In an example, the input buffer (IB) device 1010 is configured to receive one or more matrix inputs (e.g., from a memory device or the like). This IB device 1010 can be configured similarly to the IB devices shown previously (e.g., FIGS. 3A and 3B). Each such matrix input can be characterized by a first format and having at least a first input portion and a second input portion. These input portions are segmented portions of the matrix input to be processed in parallel by the compute device 1020. Depending on the embodiment, the matrix input may have a plurality of input portions, including matrix weight and activation portions (see FIG. 10B).

The IB device 1010 can receive a first matrix input or a plurality of matrix inputs in the first format from an input converter device configured to convert the matrix input(s) to the first format. This input converter device, such as a CPU (e.g., tile CPU 221 shown in FIG. 2B), an inline input converter 1012 (shown in dotted lines) coupled to the IB device 1010, or the like. Referring to previous examples, the matrix input(s) may be in an FP format, a Bfloat format, or the like. The first format can be a BFP format, a fixed point format, or the like. Other formats may also be used as long as the first format allows for the converted segmentation of the matrix data from the original format.

Merely by way of example, the matrix compute apparatus can be configured to perform matrix computations in an integer numerical format. In such cases, the compute apparatus can be configured to process the matrix input in data portions that can fit within the integer format. For example, each of the plurality of compute units can be configured for matrix computations in an int8 format and the matrix inputs can be in an FP16 format in a 64×64 byte tile configuration. In this case, the input converter device (e.g., tile CPU, inline input converter 1012, etc.) converts the FP16 matrix input to a 24-bit block floating point (BFP24) format, with a 16-bit mantissa and an 8-bit exponent. The mantissa can then be split into the two 8-bit portions, a most significant byte (MSB) portion and a least significant byte (LSB) portion, to be processed in parallel by the compute device 1020.

In an example, the compute device 1020 includes a plurality of compute units 1022 having at least a first compute unit 1022 and a second compute unit 1022. This pair of compute units can be configured to perform matrix computations for matrix inputs in a non-native format. More specifically, the first compute unit 1022 can be configured to determine a first matrix output using at least the first input portion, and the second compute unit 1022 can be configured to determine a second matrix output using at least the second input portion. Then, the compute device 1020 can be configured to determine a combined matrix output in a second format using the first matrix output and the second matrix output. In a specific example, the compute device 1020 determines the combined matrix output by shifting the first matrix output and adding the shifted first matrix output to the second matrix output.

In an example, each of the matrix inputs includes a matrix weight and a matrix activation. Each of the matrix weight inputs can include a matrix weight exponent and a matrix weight mantissa. Referring back to the FP16 example, the matrix weight exponent includes 8 bits and the matrix weight mantissa includes 16 bits that can be separated into an 8-bit MSB portion and an 8-bit LSB portion. Similarly, the matrix activation exponent also includes 8 bits and the matrix activation mantissa also includes 16 bits that can be separated into an 8-bit MSB portion and an 8-bit LSB portion. In this case, the compute device determines the first matrix output by performing a dot product process using the matrix activation and MSB portion of the matrix weight mantissa. Similarly, the compute device determines the second matrix output by performing a dot product process using the matrix activation and the LSB portion of the matrix weight mantissa.

Although the previous example only discusses segmenting the matrix input data into two portions, other examples may segment the data in to a plurality of data portions that are processed in a parallel by a plurality of compute units. In such cases, the compute device 1020 will determine a plurality of matrix outputs using similar shifting and addition processes to combine these matrix outputs into the combined matrix output with each data portion positioned in the appropriate order. These portions can also be stored in the segmented portions that match the native format of the compute device. Those of ordinary skill in the art will recognize other variations, modifications, and alternatives to the choices of data formats and data segmentation.

Considering the FP16 example, the first input portion is the MSB weight portion, while the second input portion is the LSB weight portion. The first compute unit 1022 would be configured to determine the first matrix output using the MSB portion, while the second compute unit 1022 would be configured to determine the second matrix output using the LSB portion. The matrix outputs are combined as shown in FIG. 10B by shifting the MSB portion by 8 bits and adding with LSB portion. The resulting combined matrix output would have a 38-bit mantissa (for a 64×64 matrix) and an 8-bit exponent, which can be denoted as a BFP46-1 format.

In an example, the compute device includes an alignment device 1024 coupled to the plurality of compute units 1022. The alignment device 1024 can be configured to determine a rounded matrix output in a third format using the combined output. This rounding process may be used to prepare the matrix output for a subsequent partial products reduction (PPR) process. In the FP16 example, the combined matrix output in the BFP46-1 format can be rounded down to a matrix output in a BFP32-1 format. In another example, the BFP46-1 combined matrix output can be converted to an FP32 matrix output by the alignment device 1024 or a data converter coupled to the alignment device 1024.

In an example, a PPR device 1026 is coupled to the alignment device 1024. The PPR device 1026 can be configured to determine a reduced matrix output using the rounded matrix output. The PPR process may be used to prepare the matrix output for subsequent conversion the original data format (e.g., FP16) to be stored in the OB device 1030.

In an example, the compute device 1020 also includes a compute converter 1028 configured to determine a first converted matrix output in a converted output format using the previous matrix outputs. In the FP16 example, the compute converter 1028 converts the reduced matrix output in the BFP32-1 format to an FP16 matrix output. In the case that the combined matrix output is converted to an FP32 format, the compute converter 1028 converts the reduced matrix output in the FP32 format to an FP16 matrix output.

In an example, the OB device 1030 is configured to store the resulting converted matrix output. This OB device 1030 can be configured similarly to the OB devices shown previously (e.g., FIGS. 3A and 3B). As discussed for the IB device 1010 in the FP16 example, the OB device 1030 can be configured to store the matrix outputs in a 64×64 byte tile configuration. Additional details of the matrix data conversion and computation process are discussed with reference to FIG. 10B.

Embodiments of this matrix compute apparatus and its related methods can provide many benefits. The present method and apparatus enables the computational handling of matrix inputs in different data formats that can be segmented into portions that are compatible with a native format. Also, this multi-format capability can be accomplished without requiring entirely separate hardware and compute pathways. Further, these benefits can be realized in IC chips and chiplet devices with minimal added cost of silicon area.

FIG. 10B is a simplified diagram illustrating a method of data format conversion using data segmentation and parallel processing in a matrix compute apparatus 1002 according to an example of the present invention. As shown, apparatus 1002 includes the IB device 1010 and the compute device 1020 with a plurality of compute units 1022 numbered from 0 to N, an alignment device 1024, a PPR device 1026, and a compute converter 1028.

As discussed in a previous example, each of the matrix inputs can include a matrix weight and a matrix activation. Each of the matrix weight inputs can include a matrix weight exponent and a matrix weight mantissa. Referring back to the FP16 example, the matrix weight exponent includes 8 bits and the matrix weight mantissa includes 16 bits that can be separated into an 8-bit MSB portion and an 8-bit LSB portion. In this case, the matrix activation exponent also includes 8 bits and the matrix activation mantissa also includes 16 bits that can be separated into an 8-bit MSB portion and an 8-bit LSB portion.

In this case, the first portion of the matrix weight (e.g., MSB) is stored in a first compute unit 1022-0 (shown as IMC0) while the second portion of the matrix weight (e.g., LSB) is stored in a second compute unit 1022-4 (shown as IMC4). The compute device 1020 determines the first matrix output by performing a dot product process using the matrix activation and the first portion of the matrix weight, and determines the second matrix output by performing a dot product process using the matrix activation and the second portion of the matrix weight. Then, the first matrix output is shifted (by 8 bits in the FP16 example) and added to the second matrix output to determine the combined matrix output.

Subsequently, the alignment device 1024 can determine the rounded matrix output from the combined matrix output, and the PPR device 1026 can determine the reduced matrix output from the rounded matrix output. Further, the compute converter 1028 can determine a converted matrix output from the reduced matrix output. A flow diagram of the matrix outputs is shown in FIG. 10B within dotted lines with respect to components of the compute device 1020.

As discussed previously, other examples may segment the data in to a plurality of data portions that are processed in a parallel by a plurality of compute units. In such cases, the compute device 1020 will determine a plurality of matrix outputs using similar shifting and addition processes to combine these matrix outputs into the combined matrix output with each data portion positioned in the appropriate order. These portions can also be stored in the segmented portions that match the native format of the compute device (e.g., int8 compute unit configured to process FP16 matrix input). Further, steps for processing the matrix outputs, along with their respective hardware components, may be added, removed, or rearranged depending upon the application. Those of ordinary skill in the art will recognize other variations, modifications, and alternatives to the choices of data formats and data segmentation.

While the above is a full description of the specific embodiments, various modifications, alternative constructions and equivalents may be used. As an example, the AI accelerator apparatus and chiplet devices can include any combination of elements described above, as well as outside of the present specification. Therefore, the above description and illustrations should not be taken as limiting the scope of the present invention which is defined by the appended claims.

What is claimed is:

1. A matrix compute apparatus configured as an integrated circuit (IC) for an AI accelerator IC, the apparatus comprising:
an input buffer (IB) device configured to receive a first matrix input, the first matrix input being characterized by a first format and having at least a first input portion and a second input portion;
a compute device coupled to the IB device, the compute device comprising a plurality of compute units having at least a first compute unit and a second compute unit, the first compute unit being configured to determine a first matrix output using at least the first input portion, and the second compute unit being configured to determine a second matrix output using at least the second input portion, and the compute device being configured to determine a first combined matrix output in a second format using the first matrix output and the second matrix output;
wherein the compute device comprises a compute converter configured to determine a first converted matrix output in a converted output format using the first combined matrix output; and
an output buffer (OB) device coupled to the compute device, the OB device being configured to store the first converted matrix output.

2. The apparatus of claim 1 wherein the compute device comprises an alignment device coupled to the plurality of compute units, the alignment device being configured to determine a first rounded matrix output in a third format using the first combined matrix output.

3. The apparatus of claim 2 wherein the compute device comprises a partial products reduction (PPR) device coupled to the alignment device, the PPR device being configured to determine a first reduced matrix output using the first rounded matrix output, and wherein the compute converter is configured to determine the first converted matrix output using the first reduced matrix output.

4. The apparatus of claim 3 wherein the first format comprises a first block floating point format;
wherein the second format comprises a second block floating point format;
wherein the third format comprises a third block floating point format; and
wherein the converted output format comprises a floating point format.

5. The apparatus of claim 3 wherein the first format comprises a BFP26-64 format;
wherein the second format comprises a BFP46-1 format;
wherein the third format comprises a BFP32-1 format;
wherein the converted output format comprises an FP16 format or a Bfloat16 format; and
wherein each of the first matrix output and the second matrix output is characterized by a 64×64 byte tile configuration.

6. The apparatus of claim 1 further comprising a Single Instruction, Multiple Data (SIMD) device coupled to the OB device;
wherein the IB device, the compute device, the OB device, and the SIMD device are configured within a first compute path as a first IB device, a first compute device, a first OB device, and a first SIMD device, respectively; and
further comprising one or more second compute paths, each of the additional compute paths having a second IB device, a second compute device coupled to the second IB device, a second OB device coupled to the second compute device, and a second SIMD device coupled to the second OB device.

7. The apparatus of claim 1 wherein the compute device is configured to shift the first matrix output and to add the shifted first matrix output to the second matrix output to determine the first combined matrix output.

8. The apparatus of claim 1 wherein the first matrix input comprises a first matrix weight input and a first matrix activation input; wherein the first matrix weight input comprises a first matrix weight exponent and a first matrix weight mantissa, the first matrix weight mantissa having a most significant byte (MSB) portion and a least significant byte (LSB) portion; and wherein the first matrix activation input comprises a first matrix activation exponent and a first matrix activation mantissa;
wherein the first compute unit is configured to store the MSB portion of the first matrix weight mantissa and to determine the first matrix output using the MSB portion of the first matrix weight mantissa and the first matrix activation mantissa; and
wherein the second compute unit is configured to store the LSB portion of the first matrix weight mantissa and to the determine the second matrix output using the LSB portion of the first matrix weight mantissa and the first matrix activation mantissa.

9. The apparatus of claim 8 wherein the compute device is configured to shift the first matrix output and to add the shifted first matrix output to the second matrix output to determine the first combined matrix output.

10. The apparatus of claim 8 wherein the compute device comprises an alignment device coupled to the plurality of compute units, the alignment device being configured to round the first combined matrix output to determine a first rounded matrix output in a third format.

11. The apparatus of claim 10 wherein the compute device comprises a partial products reduction (PPR) device coupled to the alignment device, the PPR device being configured to reduce the first rounded matrix output to determine a first reduced matrix output; and
wherein the compute converter is configured to determine the first converted matrix output using the first reduced matrix output.

12. The apparatus of claim 1 wherein each of the plurality of compute units is configured for an integer numerical format; and wherein the MSB portion is characterized by a signed integer and the LSB portion is characterized by an unsigned integer.

13. The apparatus of claim 1 further comprising an input converter device coupled to IB device, the input converter device being configured to convert the first matrix input from a floating point format to the first format.

14. A chiplet device, the device comprising:
a plurality of tiles, each of the tiles comprising
a plurality of slices, and a central processing unit (CPU) coupled to the plurality of slices;
wherein each of the plurality of slices comprises:
an input buffer (IB) device configured to receive a first matrix input, the first matrix input being characterized by a first format and having at least a first input portion and a second input portion;
a compute device coupled to the IB device, the compute device comprising a plurality of compute units having at least a first compute unit and a second compute unit, the first compute unit being configured to determine a first matrix output using at least the first input portion, and the second compute unit being configured to determine a second matrix output using at least the second input portion, and the compute device being configured to determine a first combined matrix output in a second format using the first matrix output and the second matrix output;
wherein the compute device comprises a compute converter configured to determine a first converted matrix output in a converted output format using the first combined matrix output; and
an output buffer (OB) device coupled to the compute device, the OB device being configured to store the first converted matrix output.

15. The device of claim 14 wherein the first matrix input comprises a first matrix weight input and a first matrix activation input; wherein the first matrix weight input comprises a first matrix weight exponent and a first matrix weight mantissa, the first matrix weight mantissa having a most significant byte (MSB) portion and a least significant byte (LSB) portion; and wherein the first matrix activation input comprises a first matrix activation exponent and a first matrix activation mantissa;
wherein the first compute unit is configured to store the MSB portion of the first matrix weight mantissa and to determine the first matrix output using the MSB portion of the first matrix weight mantissa and the first matrix activation mantissa;
wherein the second compute unit is configured to store the LSB portion of the first matrix weight mantissa and to the determine the second matrix output using the LSB portion of the first matrix weight mantissa and the first matrix activation mantissa; and
wherein the compute device is configured to shift the first matrix output and to add the shifted first matrix output to the second matrix output to determine the first combined matrix output.

16. The device of claim 14 wherein the compute device comprises an alignment device coupled to the plurality of compute units, the alignment device being configured to determine a first rounded matrix output in a third format using the first combined matrix output; and
wherein the compute device comprises a partial products reduction (PPR) device coupled to the alignment device, the PPR device being configured to determine a first reduced matrix output using the first rounded matrix output; and
wherein the compute converter is configured to determine the first converted matrix output using the first reduced matrix output.

17. The apparatus of claim 14 wherein each of the plurality of compute units is configured for an integer numerical format; and wherein the MSB portion is characterized by a signed integer and the LSB portion is characterized by an unsigned integer.

18. The apparatus of claim 14 wherein the CPU is configured to convert the first matrix input from a floating point format to the first format.

19. The device of claim 14 wherein each of the plurality of slices comprises an input converter device coupled to IB device, the input converter device being configured to convert the first matrix input from a floating point format to the first format.

20. An AI accelerator apparatus, the apparatus comprising:
a plurality of chiplets, each of the chiplets comprising a plurality of tiles, and each of the tiles comprising a plurality of slices, a central processing unit (CPU) coupled to the plurality of slices;
wherein each of the plurality of slices comprises:
an input buffer (TB) device configured to receive a first matrix input from the CPU in a first format, the first matrix input having a first matrix weight input and a first matrix activation input, wherein the first matrix weight input comprises a first matrix weight exponent and a first matrix weight mantissa, the first matrix weight mantissa having a most significant byte (MSB) portion and a least significant byte (LSB) portion; and wherein the first matrix activation input comprises a first matrix activation exponent and a first matrix activation mantissa;
a digital in-memory compute (DIMC) device coupled to the IB device, the DIMC device comprising a plurality of compute units having at least a first compute unit and a second compute unit, an alignment device coupled to the plurality of compute units, and a partial products reduction (PPR) device coupled to the alignment device;
wherein the first compute unit is configured to store the MSB portion of the first matrix weight mantissa and to determine the first matrix output using the MSB portion of the first matrix weight mantissa and the first matrix activation mantissa;
wherein the second compute unit is configured to store the LSB portion of the first matrix weight mantissa and to the determine the second matrix output using the LSB portion of the first matrix weight mantissa and the first matrix activation mantissa;
wherein each of the plurality of compute units is configured for an integer numerical format; and wherein the MSB portion is characterized by a signed integer and the LSB portion is characterized by an unsigned integer;
wherein the compute device is configured to shift the first matrix output and to add the shifted first matrix output to the second matrix output to determine a first combined matrix output in a second format;
wherein the alignment device is configured to determine a first rounded matrix output in a third format using the first combined matrix output;
wherein the PPR device is configured to determine a first reduced matrix output using the first rounded matrix output; and
wherein the compute device comprises a compute converter configured to determine a first converted matrix output in a converted output format using the first reduced matrix output; and
an output buffer (OB) device coupled to the DIMC device, the OB device being configured to store the first converted matrix output.
